(19) United States
(12) Patent Application Publication
(10) Pub. No.: US 2024/0412953 A1
(43) Pub. Date: Dec. 12, 2024

(54) APPARATUSES AND SYSTEMS FOR AMMONIA/CHLORINE CHEMISTRY SEMICONDUCTOR PROCESSING

(71) Applicant: Lam Research Corporation, Fremont, CA (US)

(72) Inventors: Bradley Taylor Streng, Tigard, OR (US); Aaron Durbin, Portland, OR (US); Aaron Blake Miller, West Linn, OR (US); Rachel E. Batzer, Tigard, OR (US); Christopher Nicholas Iadanza, Tualatin, OR (US)

(21) Appl. No.: 18/700,642

(22) PCT Filed: Oct. 7, 2022
(86) PCT No.: PCT/US2022/077818

§ 371 Date: Apr. 11, 2024

Related U.S. Application Data
(60) Provisional application No. 63/262,444, filed on Oct. 12, 2021.

(51) Int. Cl. H01J 37/32

(52) U.S. Cl. CPC H01J 37/32449; H01J 37/32633; H01J 2237/002; H01J 2237/3321

(57) ABSTRACT

Disclosed herein are systems and apparatuses for facilitating semiconductor processing operations involving the use of chlorine-containing and ammonia-containing gases. The systems and apparatuses discussed herein may provide enhanced wafer uniformity and/or may reduce the potential for undesirable, and potentially hazardous, reaction byproduct build-up in such systems.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The processing of semiconductor wafers to produce integrated circuits and other structures is typically performed in a semiconductor processing tool, which may include one or more semiconductor processing chambers, each of which is configured to process one or more wafers.

Semiconductor processing tools are typically equipped with one or more controllers that are configured to control one or more systems of the semiconductor processing tool, such as wafer handling robots, valves, heaters, coolers, radio frequency generators, etc. Such controllers may be specially programmed in order to follow a particular process recipe, which is generally understood to refer to a specification of the various materials needed during the performance of a particular process, as well as to the various environmental conditions that the controller will need to cause to exist within the semiconductor processing chamber in order to perform the process. For example, a process recipe may specify that a particular gas is to be introduced to the semiconductor processing chamber at a particular flow rate and with the chamber at a particular temperature and/or pressure, and that thereafter, the semiconductor processing chamber is to be purged of that gas and another gas is to then be introduced into the semiconductor processing chamber at a corresponding temperature and/or pressure. Process recipes may be quite complex and may involve multiple sequential and/or parallel flows of different gases into the semiconductor processing chamber.

Discussed herein are systems and apparatuses for addressing particular issues that may arise in semiconductor processing systems that are configured to perform, for example, process recipes involving the use of ammonia-containing and halogen-containing gases.

### SUMMARY

Details of one or more implementations of the subject matter described in this specification are set forth in the accompanying drawings and the description below. Other features, aspects, and advantages will become apparent from the description, the drawings, and the claims.

In some implementations, a semiconductor processing tool may be provided that includes a semiconductor processing chamber, a remote plasma generator, a conduit configured to provide fluidic communication between the remote plasma generator and the semiconductor processing chamber, a conduit cooling system configured to controllably cool the conduit, and a controller. The conduit cooling system may be configured to be transitionable between at least a first cooling state and a second cooling state, the conduit cooling system may have a higher heat-removal rate in the first cooling state than in the second cooling state, and the controller may be configured to cause the conduit cooling system to be in the first cooling state during first periods of time when plasma from the remote plasma generator is flowing into the semiconductor processing chamber via the conduit, and cause the conduit cooling system to be in the second cooling state during second periods of time when the remote plasma generator is not flowing plasma into the semiconductor processing chamber via the conduit.

In some implementations, the controller may be further configured to cause the semiconductor processing chamber to perform one or more film deposition operations by, at least in part, flowing ammonia-containing gas and one or more halogen-containing gases into the semiconductor processing chamber.

In some implementations, the semiconductor processing tool may further include a fluid inlet and a conduit cooling system valve. In such implementations, the conduit cooling system may include one or more conduit coolant flow paths that extend along at least a portion of the conduit, the conduit cooling system valve may be fluidically connected with the one or more conduit coolant flow paths and configured to be transitionable between a first state and a second state, and the conduit cooling system valve, in the first state, may be configured to cause an amount of fluid from the fluid inlet that is flowable through the one or more conduit coolant flow paths for a given back pressure at the fluid inlet to be higher as compared with the amount of the fluid from the fluid inlet that is flowable through the one or more conduit coolant flow paths for the given back pressure at the fluid inlet when the conduit cooling system valve is in the second state.

In some implementations, the conduit cooling system valve may be configured to cause no fluid from the fluid inlet to be flowable through the one or more conduit coolant flow paths when in the second state.

In some implementations, the conduit cooling system valve may be a two-way valve with a first port and one or more second ports, and fluid entering the valve via the first port may not exit the valve except via the one or more second ports.

In some implementations, the conduit cooling system valve may have a first port, a second port, and a third port. The second port may be fluidically connected with the one or more conduit coolant flow paths, the conduit cooling system valve may be configured to cause a greater portion of fluid that is flowed into the conduit cooling system valve via the first port to flow out of the second port when the conduit cooling system valve is in the first state than is flowed out of the second port when the conduit cooling system valve is in the second state, and the conduit cooling system valve may be configured to cause a smaller portion of fluid that is flowed into the conduit cooling system valve via the first port to flow out of the third port when the conduit cooling system valve is in the first state than is flowed out of the third port when the conduit cooling system valve is in the second state.

In some implementations, the semiconductor processing tool may further include a remote plasma generator cooling system configured to controllably cool the remote plasma generator. In such implementations, the remote plasma generator cooling system may include one or more remote plasma generator coolant flow paths, the one or more remote plasma generator coolant flow paths may be fluidically connected with the conduit cooling system valve via the first port, and the conduit cooling system valve may be configured to permit fluid flow through the one or more remote plasma generator coolant flow paths regardless of which of the first and second states the conduit cooling system valve is in.

In some implementations, the semiconductor processing tool may further include a fluid outlet, an outlet flow path, and a bypass flow path. In such implementations, the one or more conduit coolant flow paths may be fluidically connected with the fluid outlet by the outlet flow path such that the one or more conduit coolant flow paths are fluidically interposed between the fluid outlet and the conduit cooling system valve with respect to fluid flow through the conduit cooling system, the third port of the conduit cooling system valve may be fluidically connected with the outlet flow path by the bypass flow path, and the one or more conduit coolant flow paths may be fluidically interposed between the conduit cooling system valve and a location where the bypass flow path fluidically connects with the outlet flow path.

In some implementations, the one or more conduit coolant flow paths may include a tube that is helically wound around the conduit.

In some implementations, the one or more conduit coolant flow paths may include a conduit coolant flow path formed between the portion of the conduit and a sleeve that encloses the portion of the conduit.

In some implementations, the conduit may include one or more conduit valves that are configured to be controllably switched between an open state and a closed state. In such implementations, the one or more conduit valves, in the closed state, may seal off the semiconductor processing chamber from the remote plasma generator, and the one or more conduit valves, in the open state, may place the remote plasma generator in fluidic communication with the semiconductor processing chamber.

In some implementations, the controller may be further configured to cause the one or more conduit valves to be in the open state during the first periods of time and cause the one or more conduit valves to be in the closed state during the second periods of time.

In some implementations, a semiconductor processing tool may be provided that includes a semiconductor processing chamber, a baffle plate, and an exhaust foreline. In such implementations, the semiconductor processing chamber may include an interior volume defined, at least in part, by one or more sidewalls of the semiconductor processing chamber and a floor of the semiconductor processing chamber, the floor may include a plenum channel that extends around an interior region of the floor of the semiconductor processing chamber, the baffle plate may cover the plenum channel and may have a plurality of openings arranged along a circular path, the baffle plate may divide the interior volume into a plenum volume defined by the plenum channel and a first side of the baffle plate and a chamber volume that is on a second side of the baffle plate from the first side, each opening may fluidically connect the plenum volume with the chamber volume, and the openings may have a first total cross-sectional area, the exhaust foreline may have a second cross-sectional area where the exhaust foreline connects with the semiconductor processing chamber, and the first total cross-sectional area may be between 30% and 55% of the second cross-sectional area.

In some implementations, each opening may be an arcuate slot following an arcuate path that has a center point that is coincident with a center of the circular path.

In some implementations, each arcuate slot may be the same size and shape.

In some implementations, each arcuate slot may have a radial width of between 0.18″ and 0.14″.

In some implementations, the baffle plate may have a thickness of between 0.25″ and 0.5″.

In some implementations, the semiconductor processing tool may further include a pedestal configured to support a semiconductor wafer within the semiconductor processing chamber and a showerhead configured to distribute one or more processing gases across the pedestal. In such implementations, the one or more sidewalls may define a nominal inner perimeter of the semiconductor processing chamber, a third cross-sectional area may be defined in between the nominal inner perimeter and an outermost perimeter of the pedestal, and the first total cross-sectional area may be smaller than the third cross-sectional area.

In some implementations, the first total cross-sectional area may be the smallest cross-sectional area that gas can flow through when the gas is flowed from the showerhead, into the interior volume, past the pedestal, through the baffle plate, into the plenum channel, and into the exhaust foreline.

In some implementations, a semiconductor processing tool may be provided that includes a semiconductor processing chamber that includes an interior volume defined, at least in part, by one or more sidewalls of the semiconductor processing chamber and a floor of the semiconductor processing chamber, a pedestal configured to support a semiconductor wafer within the semiconductor processing chamber, a showerhead having one or more inlets and a plurality of gas distribution ports, one or more gas supply valves configured to control a flow or flows of one or more process gases into the semiconductor processing chamber via the gas distribution ports of the showerhead, an exhaust foreline fluidically connected with the interior volume of the semiconductor processing chamber such that the pedestal is interposed between the showerhead and a location where the exhaust foreline fluidically connected with the semiconductor processing chamber, an exhaust foreline heating system configured to heat at least a first portion of the exhaust foreline, and a controller configured to control the one or more gas supply valves to cause one or more process gases to be flowed into the semiconductor processing chamber according to a process recipe and via the gas distribution ports of the showerhead during a first time period and cause the exhaust foreline heating system to maintain the first portion of the exhaust foreline at a temperature of at least 100° C. during at least part of the first time period.

In some implementations, the exhaust foreline may be made of 316L stainless steel.

In some implementations, the exhaust foreline may have one or more interior surfaces that are in fluidic communication with the interior volume of the semiconductor processing chamber, and the one or more interior surfaces may be electropolished or nickel-plated.

In some implementations, the semiconductor processing tool may further include a plenum channel heating system and a baffle plate. In such implementations, the floor may include a plenum channel that extends around an interior region of the floor of the semiconductor processing chamber, the baffle plate may cover the plenum channel and may have a plurality of openings arranged along a circular path, the plenum channel heating system may be located along a bottom surface or surfaces of the semiconductor processing chamber and may be configured to heat a portion of the semiconductor processing chamber that is beneath the baffle plate, and the controller may be further configured to cause the plenum channel heating system to maintain the portion of the semiconductor processing chamber that is beneath the baffle plate at a temperature of at least 100° C. during at least part of the first time period.

In some implementations, the controller may be further configured to cause the exhaust foreline heating system to maintain the first portion of the exhaust foreline at a temperature of between 100° C. and 130° C. during at least part of the first time period.

In some implementations, the process recipe may include at least one flow of a halogen-containing gas and at least one flow of an ammonia-containing gas.

In addition to the above-listed implementations, other implementations evident from the discussion below and the Figures are to be understood to also fall within the scope of this disclosure.

### BRIEF DESCRIPTION OF THE FIGURES

Reference to the following Figures is made in the discussion below; the Figures are not intended to be limiting in scope and are simply provided to facilitate the discussion below.

FIG. 1 depicts an example semiconductor processing tool that may be used to perform semiconductor wafer processing operations involving halogen-containing and ammonia-containing gases.

FIG. 2 depicts a diagram of an example baffle plate.

FIG. 3 depicts a plot of normalized gas velocity, as determined through finite element analysis, through the openings of two different baffle plates as a function of angular position about the center axis of the baffle plate.

FIG. 4 depicts a schematic representation of a portion of the semiconductor processing tool of FIG. 1.

FIG. 5 depicts a diagram of an example conduit cooling system.

FIG. 6 depicts a diagram of another example conduit cooling system.

FIG. 7 depicts a schematic representation of an alternate example variation of a portion of the semiconductor processing tool of FIG. 1.

FIG. 8 depicts a schematic representation of another alternate example variation of a portion of the semiconductor processing tool of FIG. 1.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As discussed above, semiconductor processing operations may be performed on semiconductor wafers in semiconductor processing chambers of semiconductor processing tools (also simply referred to herein as “tools”). Such tools are typically equipped with a controller, e.g., that includes one or more processors and one or more memory devices. The controller may be operatively connected with various subsystems of the semiconductor processing tool so as to allow the controller to control those subsystems. The one or more memory devices may, for example, include devices such as non-volatile memory, volatile memory, hard disks, and/or optical media, or any other suitable computer-readable storage device. The one or more memory devices may store computer-executable instructions which, when executed by the one or more processors, cause the one or more processors to control the various subsystems of the semiconductor processing tool in a particular manner, e.g., according to a process recipe.

The various systems discussed herein are designed for use in semiconductor processing tools that use process recipes in which halogen-containing gases and ammonia-containing gases are introduced into the semiconductor processing chamber(s) thereof in order to process a semiconductor wafer or wafers. Such gases may, depending on the particular operations being performed, be introduced in one or more repeated, sequential gas flows—optionally with a flow of a gas that is inert with respect to the active process gases used interposed between each such gas flow—or may, in some cases, be flowed into the semiconductor processing chamber at least partially in parallel, i.e., simultaneously.

Such halogen-containing gases may include, for example, gases containing chlorine, fluorine, iodine, etc., which may then react with ammonia to for one or more compounds. While the discussion below focuses on chlorine-containing gases, it will be understood that other halogen chemistries featuring other halogens may be used, and that this disclosure encompasses the use of the systems discussed herein with respect to those other chemistries as well. It will also be understood that the systems discussed herein may also be used in conjunction with semiconductor processing tools that may, for example, not utilize halogen-containing and/or ammonia-containing chemistries but which may nonetheless benefit from one or more of the systems discussed herein.

Halogen-containing chemistries may pose issues when used in conjunction with ammonia in a semiconductor processing tool. For example, chlorine-containing gases such as SiCl₄ (silicon tetrachloride), H₂SiCl₂ (dichlorosilane or “DCS”), and/or Si₂Cl₆ (hexachlorodisilane or HCDS) and ammonia-containing gases (containing NH₃) may be used in some thin-film deposition processes, such as thin nitride film deposition processes. Such gases, as well as the byproducts that result from the use of such gases in semiconductor processing operations, may be quite hazardous due to their high reactivity and high corrosivity. For example, semiconductor processing tools that utilize chlorine-containing and ammonia-containing gases may produce, among other compounds, gases such as hydrochloric acid (HCl), ammonium chloride (NH₄Cl), hydrofluoric acid (HF), ClxOy, and/or nitrogen oxide (NOx) as waste byproducts.

Such byproducts may present particular challenges when produced in the course of semiconductor processing operations. For example, semiconductor processing tools that use the various systems discussed herein may perform semiconductor processing operations involving halogen-containing and ammonia-containing gases at relatively high temperatures, e.g., at pedestal temperatures above 500° C. or 600° C. At such temperatures, compounds such as NH₄Cl or HCl, which may be produced if a chlorine-containing gas or gases are used, may be corrosive to materials, e.g., stainless steels, commonly used in some portions of semiconductor processing tools—materials which may, at lower temps, be much more resistant to such corrosion.

This may be particularly problematic with respect to the exhaust systems that are used to evacuate such byproducts from the semiconductor processing chamber and convey them to a waste handling system, such as an abatement system. For example, when the waste gas from the semiconductor processing chamber is flowed into an exhaust foreline that may, in turn, convey that waste gas to an abatement system for safe disposal, the exhaust foreline may tend to be at a significantly lower temperature, e.g., less than 100° C., as compared with the temperature within the semiconductor processing chamber, e.g., greater than 500° C. As a result, compounds such as, in particular, NH₄Cl may start to deposit onto surfaces thereof. As such exhaust forelines are typically constructed of stainless steel, such deposition will increase the exposure of such material to such byproducts, resulting in an undesirable increase in corrosion in the exhaust foreline material.

In order to prevent such deposition, the exhaust foreline may, for example, be heated to an elevated temperature along most or all of its length using, for example, one or more conformal resistance heating elements. For example, the tubing or conduit that is used for the exhaust foreline may be wrapped or wound in resistive heating tape that is then electrically powered in order to cause the resistive heating tape to heat up. By using such an exhaust foreline heating system to heat the exhaust foreline to a temperature of 100° C. or higher, such byproducts may be prevented, or at least discouraged, from depositing on surfaces of the exhaust foreline at the pressures typically present in such locations, e.g., at pressures of between 1 to 30 Torr.

Another issue that may prove problematic in semiconductor processing tools that use process chemistries such as those discussed above is non-uniformities in the temperature or pressure that may affect wafer processing uniformity.

For example, such processes may be particularly sensitive to pressure differences around the circumference of the wafer which may occur when the exhaust foreline is connected with the semiconductor processing chamber off-center. To mitigate such pressure differences, a specially engineered baffle plate may be used that has a total open cross-sectional area through which gas may flow that is between 30% and 55% of the total cross-sectional area of the exhaust foreline. Such a baffle plate may, for example, provide for gas flow that has less than 20% circumferential non-uniformity across a wide range of pressure and flow conditions that may be used in such semiconductor processing tools, e.g., pressures between 1 and 30 Torr and flow rates of 1 to 40 standard liters per minute.

Another issue that may arise in some such semiconductor processing tools may occur in conjunction with the use of a remote plasma generator. For example, such a semiconductor processing tool may be equipped with a remote plasma generator that may be used to periodically perform a plasma cleaning operation on the semiconductor processing chamber by flowing a plasma thereinto. The remote plasma generator may be fluidically connected with the semiconductor processing chamber by a conduit. The conduit may absorb heat from the plasma that may cause it to reach temperatures that are unsafe or that may compromise its structural integrity; to mitigate this, the conduit may be equipped with a cooling system that acts to remove heat therefrom, thereby allowing the conduit to be kept to a desired temperature level.

Such a cooling system may, for example, be configured to be activated when plasma is being flowed through the conduit but may also be configured to not be activated when plasma is not flowing through the conduit—or at least not activated during processing of a wafer. In systems that see elevated pedestal temperatures during semiconductor processing operations, e.g., temperatures of 500° C. or more, the chamber walls may, for example, be kept at a temperature of ˜80° C. and the temperature differential between the cooled conduit (which may be kept at an even lower temperature) and the chamber walls may actually result in a marked “cold spot” along the interior wall of the semiconductor processing chamber where the conduit fluidically connects therewith. Such a “cold spot” may cause byproducts that result from the process gas flows into the chamber to preferentially deposit on those surfaces over other portions of the chamber. This may, in turn, result in undesirable concentrations of solidified byproduct that may accumulate around the fluidic connection of the conduit to the semiconductor processing chamber. Such concentrations may, for example, require longer duration plasma cleaning cycles to remove than may be required for more evenly distributed deposition of such byproducts on the walls of the semiconductor processing chamber and/or may result in a higher likelihood of such byproducts potentially solidifying and then flaking off and contaminating a wafer being processed in the semiconductor processing chamber. By turning off the cooling system during wafer processing operations, such a “cold spot”—and the complications arising therefrom—may be avoided.

Such systems are discussed in more detail below with reference to the Figures.

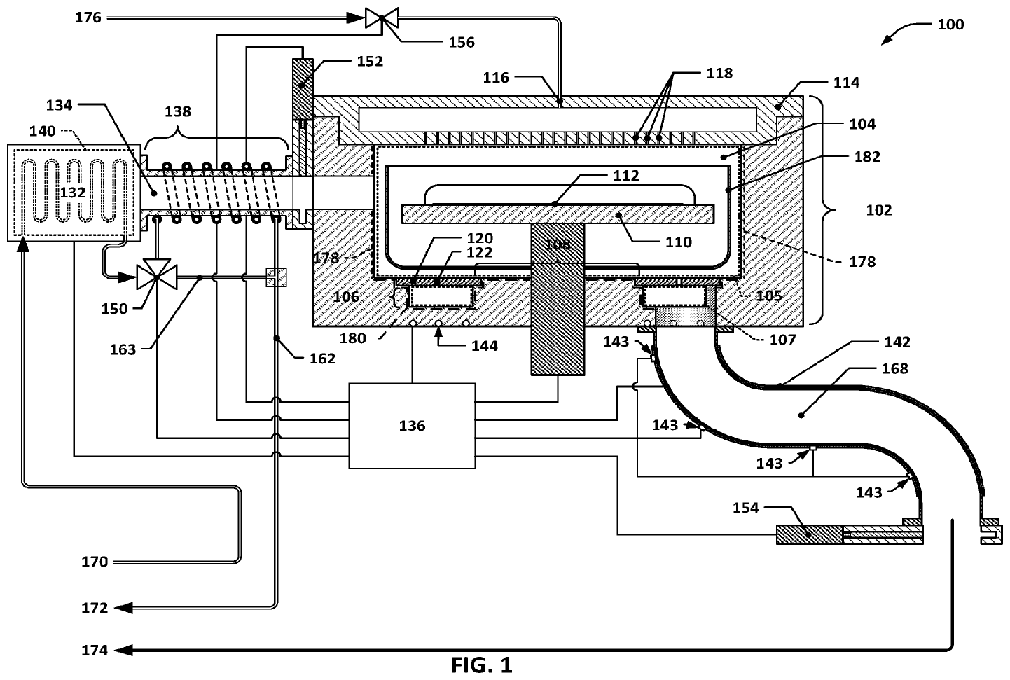

FIG. 1 depicts an example semiconductor processing tool that may be used to perform semiconductor wafer processing operations involving halogen-containing and ammonia-containing gases. As seen in FIG. 1, a semiconductor processing tool 100 may include a semiconductor processing chamber 102 that has an interior volume 104 at least partially defined by sidewalls 178 and a floor 180 of the semiconductor processing chamber 102. The interior volume 104 of the semiconductor processing chamber 102 may be partitioned by a baffle plate 120 into a chamber volume 105 and a plenum volume 107. The plenum volume 107, for example, may be defined by a plenum channel 106 in the floor 180 of the semiconductor processing chamber 102. The plenum channel 106 may, for example, be an annular or C-shaped channel in the floor 180 of the semiconductor processing chamber 102 that encircles an interior region 108 of the floor 180. A plenum channel heating system 144 may be provided that may be used to heat the plenum channel to an elevated temperature, e.g., 100° C. or higher. For example, one or more resistive heating elements may be provided in the underside of the semiconductor processing chamber 102 that may be used to provide heat to the plenum channel 106.

The baffle plate 120 may have a plurality of openings 122 therethrough that permit gas from the chamber volume 105 to flow into the plenum volume 107 before reaching exhaust foreline 168, which may then conduct such gas to an abatement system 174. An exhaust valve 154 may be provided on the exhaust foreline 168 to allow the conductance through the exhaust foreline 168 to be adjusted (or to allow the flow of gas through the exhaust foreline to be completely shut off). The exhaust foreline 168 may also be equipped with an exhaust foreline heating system 142, which may be used to heat the exhaust foreline 168 to an elevated temperature to discourage byproducts from depositing therein.

The semiconductor processing chamber 102 may also include a pedestal 110 that may be used to support a wafer 112 during semiconductor processing operations. A showerhead 114 that includes one or more inlets 116 and a plurality of gas distribution ports 118 may be provided; the showerhead 114 may, as shown, be a single-plenum showerhead. However, in other implementations, a multi-plenum showerhead, e.g., a dual-plenum showerhead, may be used to allow different gases to be flowed into the interior volume 104 of the semiconductor processing chamber 102 via separate flow paths such that those gases remain fluidically isolated from one another within the showerhead 114. Such gases may, for example, be provided by one or more gas sources 176. The flow of gas from the one or more gas sources 176 may be controlled by one or more gas supply valves 156, which may be controlled to adjust the flow (or non-flow) of such gases.

The semiconductor processing tool 100 may also be equipped with a remote plasma generator or source 132 that may be fluidically connected with the semiconductor processing chamber 102 by a conduit 134. The conduit 134 may, in turn, have a conduit cooling system 138 that is configured to cool the conduit 134 and may also include a conduit valve 152 that may be used to adjust the conductivity of the conduit, or to shut off the conduit completely from the semiconductor processing chamber 102. The remote plasma generator 132 may, for example, have a remote plasma generator cooling system 140 that may be configured to cool the remote plasma generator 132. Coolant provided by coolant supply 170 may be circulated through the conduit cooling system 138 and/or the remote plasma generator cooling system 140 before being returned to coolant return 172. The coolant supply 170 and the coolant return 172 may, for example, be provided as part of facilities utilities to which the semiconductor processing tool 100 is fluidically connected. The coolant provided to the conduit cooling system 138 may be caused to flow through a conduit cooling system valve 150 and may flow back to the coolant return 172 via an outlet flow path 162.

A controller 136 may be provided that may be operatively connected with the various systems discussed above. The controller may, as noted earlier, include one or more processors and one or more memory devices; the one or more memory devices may store computer-executable instructions for controlling one or more of the systems discussed above in accord with various implementations discussed herein.

As discussed above, a semiconductor processing tool such as depicted in FIG. 1 may be equipped with one or more features that provide advantages in the context of semiconductor processing using halogen-containing and ammonia-containing gases. For example, the controller 136 may be configured to cause the exhaust foreline heating system 142 to provide heat to the exhaust foreline 168 so as to keep the exhaust foreline 168 at a temperature of at least 100° C. during at least some time periods in which halogen-containing and/or ammonia-containing gases are caused by the controller 136 to be flowed into the semiconductor processing chamber 102. The controller may, for example, be operatively connected with one or more temperature sensors 143 that may be used to monitor the temperature of the exhaust foreline 168 at corresponding locations. The controller 136 may, for example, cause the exhaust foreline heating system 142 to provide more or less heat, as needed, in order to keep the temperature measured at each temperature sensor 143 at or above a threshold temperature, e.g., 100° C. For example, in some implementations, the exhaust foreline heating system may be used to keep the exhaust foreline at a temperature of between 100° C. and 130° C., although in other implementations, the exhaust foreline temperature may be kept at a threshold temperature between 100° and 200° C. In some implementations, the exhaust foreline heating system 142 may be a multi-zone exhaust foreline heating system, e.g., with multiple, separate resistive heaters that may be individually powered and controlled so as to allow separate segments of the exhaust foreline 168 to be individually controlled. In such implementations, each zone may be associated with at least one separate temperature sensor that may be used to provide for closed-loop control of that zone by the controller. Such active heating of the exhaust foreline 168 using the exhaust foreline heating system 142 allows the deposition and accumulation of solidified reaction byproducts that result from the use of halogen-containing and ammonia-containing gases to be reduced or even eliminated, thereby reducing the rate at which such byproducts may corrode the exhaust foreline 168. The exhaust foreline heating system 142 may, as depicted in FIG. 1, extend along a portion of the exhaust foreline 168, although in some implementations, such a portion may include 80%, 90%, 95%, or even 100% of the total length of the exhaust foreline.

As noted earlier, compounds such as ammonium chloride are corrosive at temperatures at greater than 100° C., even to stainless steels. While heating the exhaust foreline 168 to a temperature of 100° C. or greater would seem to potentially encourage such corrosion, such heating also serves to keep such compounds in their gaseous states, thereby avoiding deposition thereof on the interior surfaces of the exhaust foreline 168. Accordingly, the exposure of the interior of the exhaust foreline to such compounds may be relatively evenly distributed across the entire interior area of the exhaust foreline as opposed to being highly concentrated in just the regions where such compounds might otherwise be deposited in a system using an unheated exhaust foreline. This will cause whatever corrosion that occurs to be similarly distributed in nature as opposed to concentrated, thereby extending the lifespan of the exhaust foreline.

In some implementations, the exhaust foreline 168 may be made of 316L stainless steel, which is more resistant to corrosion with respect to some compounds, e.g., halogen-based byproducts, e.g., such as chlorine-based byproducts or iodine-based byproducts. The interior surface(s) of the exhaust foreline 168 may also be optionally polished in order to remove surface roughness that may act to increase the surface area available onto which waste byproduct compounds that flow through the exhaust foreline 168 may deposit. For example, by polishing the internal surfaces of the exhaust foreline 168 to a surface roughness of 25 μin or less, the resistance of the exhaust foreline 168 to deposition may be further enhanced, thereby augmenting the benefits provided by the exhaust foreline heating system 142. In some such implementations, the internal surfaces of the exhaust foreline may be electropolished to the desired degree of surface roughness. Electropolishing is an electrochemical technique in which the surfaces to be polished are immersed in an electrolyte, e.g., a concentrated acid solution, and used as an anode. A separate cathode is immersed in the same electrolyte and a current is then passed through the anode to the cathode via the electrolyte. The current causes metal on the surface of the component being polished to oxidize and dissolve, thereby smoothing the surface of the component being polished. Micropeaks that are present on the surface being polished tend to be more aggressively removed by the electropolishing process, thereby causing the surface to be rendered smoother. In stainless steels, such as 316L stainless steel, electropolishing also preferentially removes iron from the surface being polished and thus enhances the chromium/nickel content of the uppermost layer(s) of the surface being polished. Additionally or alternatively, the interior surface(s) of the exhaust foreline may be plated with a corrosion-resistant material, such as chromium or nickel. Both chromium and nickel generally exhibit high corrosion resistance against the various byproducts that may result from semiconductor processing operations involving halogen-containing and ammonia-containing gases.

As shown in FIG. 1, the exhaust foreline 168 may, in some implementations, fluidically connect with the semiconductor processing chamber 102 at a location along a plenum channel 106. The plenum volume 107 of the plenum channel 106 may be separated from the chamber volume 105 by the baffle plate 120, which may be designed so as to provide for relatively even gas flow therethrough within the particular flow regime of interest while still providing a sufficiently high flow conductance so as to support the flow rates of gas through the semiconductor processing chamber that may occur during typical semiconductor processing operations, e.g., at pressures of between 1 and 30 Torr and flow rates from 1 to 40 liters per minute. In a system such as that depicted, e.g., where gases are drawn into an exhaust foreline that is mounted off-center from the nominal center axis of the semiconductor processing chamber 102 (and the baffle plate 120 and the plenum channel 106), such parameters may generally be at cross-purposes to one another-increasing conductance through the baffle plate 120 will generally act to magnify the effect of the different flow path lengths between the off-center exhaust foreline 168 connection and different locations along the plenum channel 106 on the flow through the baffle, with the openings through the baffle that are closest to the exhaust foreline 168 connection providing the path of least resistance to gas flow and the openings through the baffle that are furthest from the exhaust foreline 168 connection providing the path of most resistance to gas flow. Thus, increasing conductance through the baffle plate 120 tends to increase circumferential non-uniformity in the gas flow through the baffle plate 120. At the same time, reducing the sizes of the openings 122 through the baffle plate 120 acts to reduce the effect of path length from each opening 122 to the exhaust foreline 168 connection with the semiconductor processing chamber 102, but will also act to reduce the conductance of the baffle plate 120.

A large variety of different baffle plate 120 designs were evaluated, including baffle plates with openings 122, e.g., arcuate slots, that were constant in size around the circumference of the baffle plate, increased in width and/or length with increasing distance from the location where the exhaust foreline 168 connected with the semiconductor processing chamber 102, multi-tier baffle plates in which gas flow was forced to change flow direction one or more times (e.g., in the radial direction and/or the circumferential direction) within the baffle plate before reaching the exhaust foreline 168, and baffle plates augmented with an additional baffle plate located beneath the baffle plate 120 within the plenum channel 106. Such baffle plates all exhibited relatively poor performance with respect to circumferential flow non-uniformity when subjected to a fluidic finite element analysis. For example, the circumferential non-uniformity of gas flow for such baffle plates was found through such analysis to range from ^{˜}50% to nearly 100%. For the sake of clarity, circumferential non-uniformity of gas flow for a baffle plate is determined by taking the difference between the highest and lowest flow velocities at the centers of the baffle openings for a given baffle plate and dividing that by the highest flow velocity in the interiors of the baffle openings (thus avoiding localized velocity reductions at the edges of the openings.

What was ultimately found to provide a desirable balance of sufficiently high flow conductance and low circumferential non-uniformity was a baffle plate that used a circular array of openings in which the total cross-sectional area of those openings was in the range of 30% to 55% of the cross-sectional area of the exhaust foreline 168 where the exhaust foreline 168 connects with the semiconductor processing chamber 102. For example, for an exhaust foreline 168 having a 4″ nominal diameter (which may a nominal wall thickness of ^{˜} 1/16″), the cross-sectional area of the exhaust foreline 168 may be ^{˜}11.5 square inches; a baffle plate having a total cross-sectional opening area of between about 4 square inches and 6 square inches may be used to achieve the desired degree of flow conductance and circumferential nonuniformity. For example, a baffle plate 120 having openings in the form of 12 arcuate slots, each approximately 0.15″ in width and similarly sized and shaped, having a total cross-sectional opening area of 4.5 square inches and arranged in a circular pattern was found via analysis to provide circumferential non-uniformity of less than 20%. The arcuate slots, for example, may follow arcuate paths that have center points that are coincident with a center of the circular pattern. In some implementations, such arcuate slots may be between 0.14″ and 0.18″ in radial width. In some additional or alternative such implementations, each arcuate slot may extend through between 22° and 28° of arc, e.g., 24° of arc. Such baffle plates may have a thickness of between about 0.25″ and 0.5″, e.g., 0.375″.

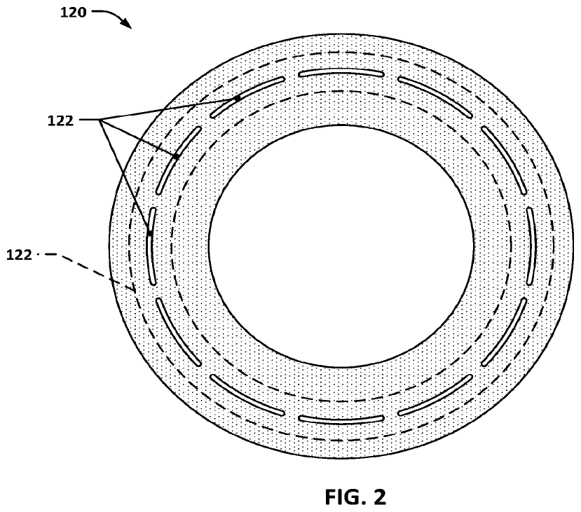

FIG. 2 depicts a diagram of such a baffle plate 120. As can be seen, the baffle plate 120 has twelve openings 122 arranged in a circular array. Each opening 122 passes through the baffle plate 120 and has an arcuate, slot-shaped cross-section in a plane perpendicular to the baffle plate 120. The openings 122 may, for example, be positioned so as to generally be centered over the plenum channel 106 when the baffle plate 120 is installed, e.g., centered within 40% to 60% of plenum channel 106 width. The baffle plate may also have other holes or passages through it, e.g., to accommodate mounting screws, lift pins, etc. Such additional through-holes are not considered to be the “openings” that provide for gas flow through the baffle plate 120, however, as such holes are typically blocked, either by screws or other equipment, after installation is complete.

By constraining the size of the openings through the baffle plate in this manner, issues that arose with similar geometries having much larger total cross-sectional opening area-to-exhaust foreline cross-sectional area ratios were sidestepped. For example, a baffle plate that similarly featured openings that took the form of 12 arcuate slots, each 0.75″ in width and having a total cross-sectional area of ^{˜}24 square inches, was found via analysis to provide drastically worse circumferential flow non-uniformity of 97%.

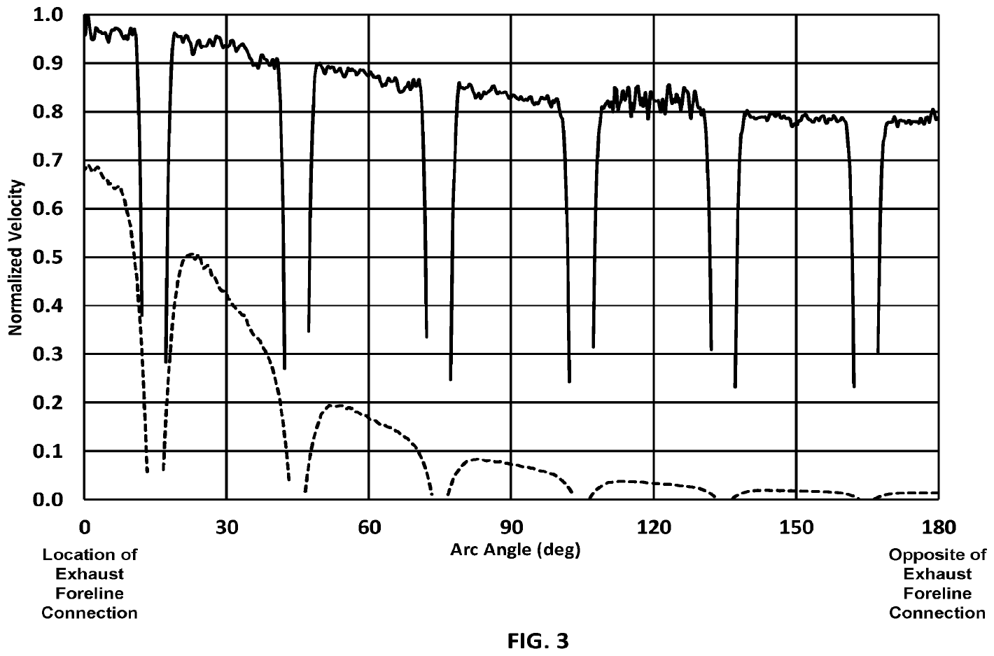

FIG. 3 depicts a plot of normalized gas velocity, as determined through finite element analysis, through the openings of two different baffle plates as a function of angular position about the center axis of the baffle plate (which may be nominally annular in shape), with the arc angle indicating the angular position relative to the center axis of the baffle plate and with 0 degrees corresponding to the center of the connection point between the exhaust foreline 168 and the semiconductor processing chamber 102 and 180 degrees corresponding to a location on the opposite side of the plenum channel 106. As the baffle plate is bilaterally symmetric in these examples, the gas velocity is only plotted for half of the circumference; the other half would be a mirror image thereof. The dotted line plot in FIG. 3 depicts the gas velocity through the openings of a baffle plate having, for example, 12 arcuate slots, each 0.75″ in width and having a total cross-sectional area of ^{˜}24 square inches. As can be seen, the flow velocity in such a baffle plate exhibits a marked drop as one traverses the circumference of the baffle plate 120 from the exhaust foreline 168 connection point to the opposite side of the baffle plate, with the gas velocity dropping nearly 97% from the maximum gas velocity seen at the location coinciding with the location where the exhaust foreline 168 connects with the semiconductor processing chamber 102. In contrast, the solid line plot in FIG. 3 depicts similar data for another baffle plate similar to the baffle plate discussed above that had 12 arcuate slots, each with a width of 0.15″ and providing a total cross-sectional opening area of ^{˜}4.5 square inches. While this baffle plate also exhibits a reduction in gas velocity as one traverses the circumference of the baffle plate 120 from the exhaust foreline 168 connection point to the opposite side of the baffle plate, the gas velocity only drops about 20% from its maximum value.

Generally speaking, the baffle plates discussed herein may be designed to have the smallest total cross-sectional open flow area that is encountered by gas that flows from the showerhead 114, past the pedestal 110, and into the exhaust foreline 168. For example, the sidewalls 178 of the chamber may define a nominal inner perimeter of the semiconductor processing chamber (e.g., excluding various apertures through the sidewalls of the semiconductor processing chamber such as wafer loading slots, viewports, etc.) and a cross-sectional open flow area may be defined in the generally ring-shaped space in between the outermost perimeter of the pedestal 110 and the nominal inner perimeter of the semiconductor processing chamber. This cross-sectional open flow area may be larger, e.g., an order of magnitude larger, than the total cross-sectional area of the openings 122 of the baffle plate 120.

By using a baffle plate designed in such a manner, the flow of gases into the plenum channel 106 through the baffle plate 120 may be caused to have much more even circumferential flow behavior, thus reducing potential on-wafer non-uniformities that may arise due to such circumferential flow non-uniformity.

As discussed above, another feature that semiconductor processing tool 100 may have is a remote plasma generator 132, which may be used to provide a plasma to the semiconductor processing chamber 102 in between wafer processing operations in order to perform a plasma clean operation. As discussed above, the remote plasma generator 132 may, for example, be fluidically connected to the semiconductor processing chamber 102 by a conduit 134 that may be used to convey the plasma generated by the remote plasma generator 132 into the semiconductor processing chamber 102. When a plasma cleaning operation is not being performed, the remote plasma generator 132 may be fluidically isolated from the semiconductor processing chamber 102 using the conduit valve 152, which may be controlled so as to close and seal the semiconductor processing chamber 102 off from the remote plasma generator 132 during such periods of time.

As discussed earlier, when plasma is flowing through the conduit 134, the heat from the plasma may cause the conduit 134 to reach temperatures that may be potentially hazardous and/or may compromise the structure of the conduit. To prevent such an occurrence, the semiconductor processing tool 100 may be equipped with a conduit cooling system 138 that is configured to cool at least a portion of the conduit. The conduit cooling system 138 may, for example, be transitionable between at least a first cooling state and a second cooling state. In the first cooling state, the conduit cooling system 138 may have a higher heat-removal rate than in the second cooling state. For example, if the conduit cooling system 138 removes heat by flowing a coolant fluid past surfaces of the conduit 134 and into a coolant return, the conduit cooling system may, in at least some instances, reduce the flow rate of the coolant in the second cooling state as opposed to the flow rate of the coolant in the first cooling state, thereby allowing less heat to be removed in the second cooling state as compared with the first cooling state. In some such implementations, the flow of coolant past the conduit 134 may simply be shut off in the second cooling state, thereby providing no cooling via the conduit cooling system 138.

The controller 136 may be configured to cause the conduit cooling system 138 to be in the first cooling state during periods of time during which plasma from the remote plasma generator 132 is being flowed through the conduit 134 and into the semiconductor processing chamber 102. The controller 136 may also be further configured to cause the conduit cooling system 138 to be in the first cooling state during periods of time during which plasma from the remote plasma generator 132 is being flowed through the conduit 134 and into the semiconductor processing chamber 102. For example, the controller 136 may be operatively connected with the conduit cooling system valve 150, which may be controlled to adjust the amount of coolant that may flow through the conduit cooling system 138.

The controller 136 may also be configured to cause the conduit cooling system 138 to conversely be in the second cooling state during periods of time during which plasma from the remote plasma generator 132 is not being flowed through the conduit 134 and into the semiconductor processing chamber 102, e.g., such as during periods of time when the conduit valve 152 is in a closed state.

In the depicted implementation, the coolant that is flowed into the conduit cooling system 138 is obtained by routing coolant from coolant supply 170 that was previously flowed through remote plasma generator coolant flow paths 160 of the remote plasma generator cooling system 140 through the conduit cooling system valve 150 and through the conduit cooling system 138 before delivering the coolant to the coolant return 172 via the outlet flow path 162.

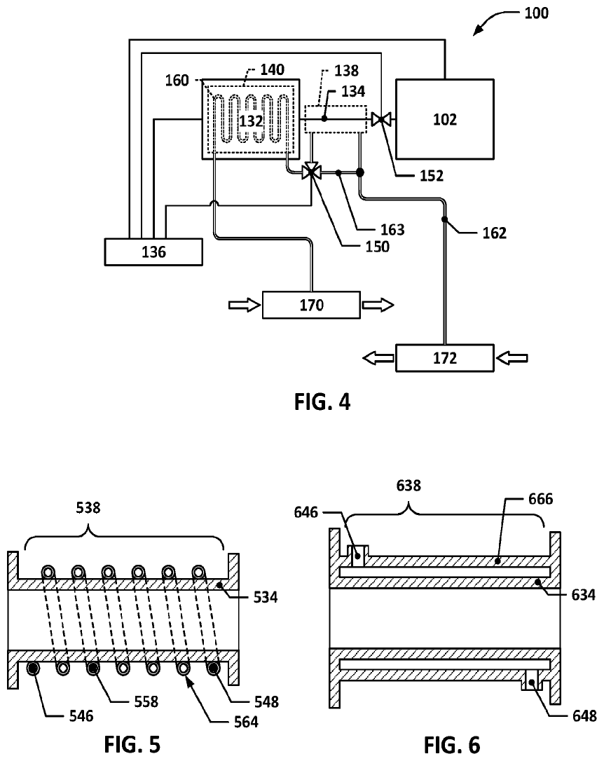

The fluidic circuit for the remote plasma generator cooling system 140 and the conduit cooling system 138 is shown in a more schematic representation in FIG. 4. As can be seen, the remote plasma generator 132 may be equipped with remote plasma generator cooling system 140 that may have one or more flow paths that convey fluid that is introduced to the remote plasma generator cooling system 140 past various systems internal to the remote plasma generator 132 that may require cooling. Such cooling systems may be standard equipment on remote plasma generators that require such cooling. If the remote plasma generator 132 requires active cooling via such a cooling system, the coolant that is used may optionally be routed, upon exiting the remote plasma generator 132, to the conduit cooling system valve 150. In this particular example, the conduit cooling system valve 150 is at least a three-way valve that is capable of switching a stream of fluid that is delivered thereto via an inlet port (a first port) between at least two outlet ports (second and third ports) thereof. One such outlet port, e.g., the second port, may be fluidically connected to one or more inlets 146 of the conduit cooling system 138. When the conduit cooling system valve 150 is in a first state, the conduit cooling system valve 150 may be configured to cause an amount of fluid from that is flowable through the one or more conduit coolant flow paths via a fluid inlet for a given back pressure at the fluid inlet to be higher as compared with the amount of the fluid from the fluid inlet that is flowable through the one or more conduit coolant flow paths for the given back pressure at the fluid inlet when the conduit cooling system valve is in the second state. In some implementations, the conduit cooling system valve 150 may, in the first state and/or the second state, cause all of the fluid flowed into the conduit cooling system valve 150 to be flowed into or not be flowed into, respectively, the conduit cooling system.

The fluid inlet, for example, may be a fitting that is configured to be connected with a coolant supply, e.g., a facility-provided coolant supply. In some implementations, the conduit cooling system valve may, in the second state, completely block all fluid flow therethrough to the conduit cooling system 138.

The coolant that flows through the conduit cooling system 138 may exit the conduit cooling system 138 via an outlet flow path 162 that may, for example, lead to a fluid outlet, e.g., a fitting that is connectable to the coolant return 172, which may return the coolant to the coolant return 172. In this depicted implementation, the other outlet port, e.g., the third port, of the conduit cooling system valve 150 is fluidically connected with the outlet flow path 162, e.g., via a T-junction. Accordingly, whatever fluid is diverted from the one or more flow paths of the conduit cooling system 138 by operation of the conduit cooling system valve 150 may instead be routed directly to the outlet flow path 162, thereby bypassing the conduit cooling system 138 completely but allowing the coolant to continue flowing. Such an arrangement may be advantageous in situations in which the remote plasma generator requires a constant supply of coolant in order to continue operating. For example, some remote plasma generators may have one or more sensors that detect whether or not coolant is being supplied to the remote plasma generator cooling system; in the event that such sensors detect that no coolant is being provided (or too little coolant), the controller of the remote plasma generator may cause the remote plasma generator to either turn off or enter a standby state. To avoid such adjustments to the operating status of the remote plasma generator 132, the conduit cooling system valve 150 may be controlled by the controller 136 to simply divert the exit coolant flow from being routed through the conduit cooling system 138 to being routed through a bypass flow path 163 to the outlet flow path 162. This allows the fluid flow of coolant—and the operation of the remote plasma generator 132—to continue uninterrupted.

During operation, the controller 136 may, in order to perform a plasma cleaning operation, cause the conduit cooling system valve 150 to be in the first state while also causing the conduit valve 152 to be in the open state, thereby placing the remote plasma generator 132 into fluidic communication with the semiconductor processing chamber 102 to allow plasma to flow into the semiconductor processing chamber 102 and causing the conduit cooling system 138 to cool the conduit 134, thereby keeping the conduit 134 at a reduced temperature. Conversely, the controller 136 may, when performing wafer processing operations, cause the conduit cooling system valve 150 to be in the second state while also causing the conduit valve 152 to be in the closed state, thereby preventing plasma from flowing into the semiconductor processing chamber 102 and preventing the conduit 134 from being cooled during the wafer processing operations. This may prevent the occurrence of a “cold” spot on the interior of the semiconductor processing chamber that may have undesirable consequences.

The conduit cooling system 138 may take any of a variety of different forms; FIGS. 5 and 6 depict two different examples of conduit cooling systems that may be used. In FIG. 5, a conduit cooling system 538 is depicted that uses one or more helically wound tubes 564 that may provide one or more conduit coolant flow paths 558 that are in contact with the outer surface of a conduit 534. While only one helically wound tube 564 is shown, it will be appreciated that multiple such helically wound tubes may be provided, if desired. Coolant may be flowed into the tube 564 via an inlet 546 and may exit the tube 564 via an outlet 548. The conduit cooling system 538 is generally similar to the conduit cooling system depicted in FIG. 1.

In FIG. 6, a conduit cooling system 638 is depicted that uses a sleeve, jacket, or other structure 666 to create one or more flow paths that surround the outer surface of the conduit 634. An inlet 646 may allow coolant to be flowed into the gap between the conduit 634 and the sleeve, jacket, or other structure 666, while an outlet 648 may be provided to allow the coolant to then exit the gap after flowing along the outer surface of the conduit 634.

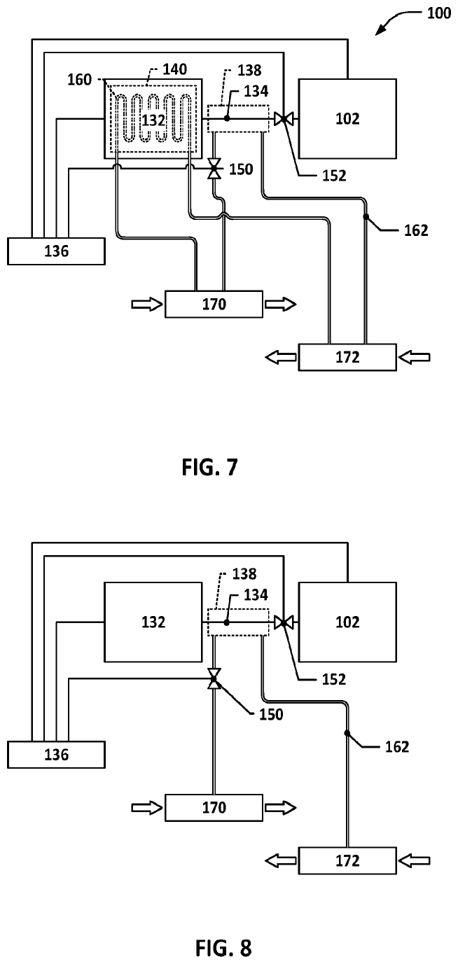

It will be appreciated that the above are only two examples of systems that may be used to provide the conduit cooling system 138; other such systems that provide similar functionality may be used in place of such examples, if desired. For example, the conduit need not be a straight conduit, as depicted, but may also, in some implementations, be provided using a curved tube, e.g., a 90° elbow. It will also be appreciated that the fluidic configuration discussed above with respect to FIG. 4 may also be modified according to the needs of a particular semiconductor processing tool. FIGS. 7 and 8 depict two alternate fluidic configurations that may be used.

FIG. 7 depicts an example fluidic configuration in which the remote plasma generator cooling system 140 is provided coolant via a separate cooling loop than is the conduit cooling system 138. In other words, coolant flows from the coolant supply 170 to both the remote plasma generator cooling system 140 and the conduit cooling system 138 in parallel, such that terminating the flow of coolant to either does not affect the other. Accordingly, the conduit cooling system valve 150 may, in this example, be a simple two-way valve, e.g., a valve that is configured to adjust (or stop entirely) the flow of coolant into the conduit cooling system 138, but without necessarily diverting it elsewhere. Such a two-way valve may, for example, be configured such that fluid that enters such a valve via a first port can only exit the valve via one or more second ports of the two-way valve.

FIG. 8 depicts another example fluidic configuration that is similar to that of FIG. 7 except that the remote plasma generator 132, in this example, does not have a remote plasma generator cooling system 140 and there is thus no coolant flow provided thereto.

As noted earlier, in some implementations, a controller may be included as part of a semiconductor processing tool, including, for example, the above-described examples. The systems discussed above may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, radio frequency (RF) generator settings, RF matching circuit settings, frequency settings, flow rate settings, fluid delivery settings, positional and operation settings, wafer transfers into and out of a tool or chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fludically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. A semiconductor processing tool comprising:
a semiconductor processing chamber;
a remote plasma generator;
a conduit configured to provide fluidic communication between the remote plasma generator and the semiconductor processing chamber;
a conduit cooling system configured to controllably cool the conduit; and
a controller, wherein:
the conduit cooling system is configured to be transitionable between at least a first cooling state and a second cooling state,
the conduit cooling system has a higher heat-removal rate in the first cooling state than in the second cooling state, and
the controller is configured to:
cause the conduit cooling system to be in the first cooling state during first periods of time when plasma from the remote plasma generator is flowing into the semiconductor processing chamber via the conduit, and
cause the conduit cooling system to be in the second cooling state during second periods of time when the remote plasma generator is not flowing plasma into the semiconductor processing chamber via the conduit.

2. The semiconductor processing tool of claim 1, wherein the controller is further configured to cause the semiconductor processing chamber to perform one or more film deposition operations by, at least in part, flowing ammonia-containing gas and one or more halogen-containing gases into the semiconductor processing chamber.

3. The semiconductor processing tool of claim 1, further comprising:
a fluid inlet; and
a conduit cooling system valve, wherein:
the conduit cooling system includes one or more conduit coolant flow paths that extend along at least a portion of the conduit,
the conduit cooling system valve is fluidically connected with the one or more conduit coolant flow paths and configured to be transitionable between a first state and a second state, and
the conduit cooling system valve, in the first state, is configured to cause an amount of fluid from the fluid inlet that is flowable through the one or more conduit coolant flow paths for a given back pressure at the fluid inlet to be higher as compared with the amount of the fluid from the fluid inlet that is flowable through the one or more conduit coolant flow paths for the given back pressure at the fluid inlet when the conduit cooling system valve is in the second state.

4. The semiconductor processing tool of claim 3, wherein the conduit cooling system valve is configured to cause no fluid from the fluid inlet to be flowable through the one or more conduit coolant flow paths when in the second state.

5. The semiconductor processing tool of claim 3, wherein:
the conduit cooling system valve is a two-way valve with a first port and one or more second ports, and
fluid entering the valve via the first port cannot exit the valve except via the one or more second ports.

6. The semiconductor processing tool of claim 3, wherein:
the conduit cooling system valve has a first port, a second port, and a third port,
the second port is fluidically connected with the one or more conduit coolant flow paths,
the conduit cooling system valve is configured to cause a greater portion of fluid that is flowed into the conduit cooling system valve via the first port to flow out of the second port when the conduit cooling system valve is in the first state than is flowed out of the second port when the conduit cooling system valve is in the second state, and
the conduit cooling system valve is configured to cause a smaller portion of fluid that is flowed into the conduit cooling system valve via the first port to flow out of the third port when the conduit cooling system valve is in the first state than is flowed out of the third port when the conduit cooling system valve is in the second state.

7. The semiconductor processing tool of claim 6, further comprising a remote plasma generator cooling system configured to controllably cool the remote plasma generator, wherein:
the remote plasma generator cooling system includes one or more remote plasma generator coolant flow paths,
the one or more remote plasma generator coolant flow paths are fluidically connected with the conduit cooling system valve via the first port, and
the conduit cooling system valve is configured to permit fluid flow through the one or more remote plasma generator coolant flow paths regardless of which of the first and second states the conduit cooling system valve is in.

8. The semiconductor processing tool of claim 7, further comprising a fluid outlet, an outlet flow path, and a bypass flow path, wherein:
the one or more conduit coolant flow paths are fluidically connected with the fluid outlet by the outlet flow path such that the one or more conduit coolant flow paths are fluidically interposed between the fluid outlet and the conduit cooling system valve with respect to fluid flow through the conduit cooling system,
the third port of the conduit cooling system valve is fluidically connected with the outlet flow path by the bypass flow path, and
the one or more conduit coolant flow paths are fluidically interposed between the conduit cooling system valve and a location where the bypass flow path fluidically connects with the outlet flow path.

9. The semiconductor processing tool of claim 3, wherein the one or more conduit coolant flow paths include a tube that is helically wound around the conduit.

10. The semiconductor processing tool of claim 3, wherein the one or more conduit coolant flow paths include a conduit coolant flow path formed between the portion of the conduit and a sleeve that encloses the portion of the conduit.

11. The semiconductor processing tool of claim 1, wherein the conduit includes one or more conduit valves that are configured to be controllably switched between an open state and a closed state, wherein:
the one or more conduit valves, in the closed state, seal off the semiconductor processing chamber from the remote plasma generator, and
the one or more conduit valves, in the open state, place the remote plasma generator in fluidic communication with the semiconductor processing chamber.

12. The semiconductor processing tool of claim 11, wherein the controller is further configured to:
cause the one or more conduit valves to be in the open state during the first periods of time, and
cause the one or more conduit valves to be in the closed state during the second periods of time.

13. A semiconductor processing tool comprising:
a semiconductor processing chamber;
a baffle plate; and
an exhaust foreline, wherein:
the semiconductor processing chamber includes an interior volume defined, at least in part, by one or more sidewalls of the semiconductor processing chamber and a floor of the semiconductor processing chamber,
the floor includes a plenum channel that extends around an interior region of the floor of the semiconductor processing chamber,
the baffle plate covers the plenum channel and has a plurality of openings arranged along a circular path,
the baffle plate divides the interior volume into a plenum volume defined by the plenum channel and a first side of the baffle plate and a chamber volume that is on a second side of the baffle plate from the first side,
each opening fluidically connects the plenum volume with the chamber volume, and the openings have a first total cross-sectional area,
the exhaust foreline has a second cross-sectional area where the exhaust foreline connects with the semiconductor processing chamber, and
the first total cross-sectional area is between 30% and 55% of the second cross-sectional area.

14. The semiconductor processing tool of claim 13, wherein each opening is an arcuate slot following an arcuate path that has a center point that is coincident with a center of the circular path.

15. The semiconductor processing tool of claim 14, wherein each arcuate slot is the same size and shape.

16. The semiconductor processing tool of claim 14, wherein each arcuate slot has a radial width of between 0.18″ and 0.14″.

17. The semiconductor processing tool of claim 13, wherein the baffle plate has a thickness of between 0.25″ and 0.5″.

18. The semiconductor processing tool of claim 13, further comprising:
a pedestal configured to support a semiconductor wafer within the semiconductor processing chamber; and
a showerhead configured to distribute one or more processing gases across the pedestal, wherein:
the one or more sidewalls define a nominal inner perimeter of the semiconductor processing chamber,
a third cross-sectional area is defined in between the nominal inner perimeter and an outermost perimeter of the pedestal, and
the first total cross-sectional area is smaller than the third cross-sectional area.

19. The semiconductor processing tool of claim 18, wherein the first total cross-sectional area is the smallest cross-sectional area that gas can flow through when the gas is flowed from the showerhead, into the interior volume, past the pedestal, through the baffle plate, into the plenum channel, and into the exhaust foreline.

20. A semiconductor processing tool comprising:
a semiconductor processing chamber that includes an interior volume defined, at least in part, by one or more sidewalls of the semiconductor processing chamber and a floor of the semiconductor processing chamber;
a pedestal configured to support a semiconductor wafer within the semiconductor processing chamber;
a showerhead having one or more inlets and a plurality of gas distribution ports;
one or more gas supply valves configured to control a flow or flows of one or more process gases into the semiconductor processing chamber via the gas distribution ports of the showerhead;
an exhaust foreline fluidically connected with the interior volume of the semiconductor processing chamber such that the pedestal is interposed between the showerhead and a location where the exhaust foreline fluidically connected with the semiconductor processing chamber;
an exhaust foreline heating system configured to heat at least a first portion of the exhaust foreline; and
a controller configured to:
control the one or more gas supply valves to cause one or more process gases to be flowed into the semiconductor processing chamber according to a process recipe and via the gas distribution ports of the showerhead during a first time period, and
cause the exhaust foreline heating system to maintain the first portion of the exhaust foreline at a temperature of at least 100° C. during at least part of the first time period.

21. The semiconductor processing tool of claim 20, wherein the exhaust foreline is made of 316L stainless steel.

22. The semiconductor processing tool of claim 20, wherein:
the exhaust foreline has one or more interior surfaces that are in fluidic communication with the interior volume of the semiconductor processing chamber, and
the one or more interior surfaces are electropolished or nickel-plated.

23. The semiconductor processing tool of claim 20, further comprising:
a plenum channel heating system; and
a baffle plate, wherein:
the floor includes a plenum channel that extends around an interior region of the floor of the semiconductor processing chamber,
the baffle plate covers the plenum channel and has a plurality of openings arranged along a circular path,
the plenum channel heating system is located along a bottom surface or surfaces of the semiconductor processing chamber and is configured to heat a portion of the semiconductor processing chamber that is beneath the baffle plate, and
the controller is further configured to cause the plenum channel heating system to maintain the portion of the semiconductor processing chamber that is beneath the baffle plate at a temperature of at least 100° C. during at least part of the first time period.

24. The semiconductor processing tool of claim 20, wherein the controller is further configured to cause the exhaust foreline heating system to maintain the first portion of the exhaust foreline at a temperature of between 100° C. and 130° C. during at least part of the first time period.

25. The semiconductor processing tool of claim 20, wherein the process recipe includes at least one flow of a halogen-containing gas and at least one flow of an ammonia-containing gas.
